(19) United States
(12) Patent Application Publication
(10) Pub. No.: US 2004/0046169 A1
(43) Pub. Date: Mar. 11, 2004

(54) Optical semiconductor device with transparent support

(76) Inventor: Patrick Daniel Perillat, Sassenage (FR)

Correspondence Address: Christopher F Regan, Allen Dyer Doppelt Milbrath & Gilchrist, P O Box 3791, Orlando, FL, 32802-3791, US

(21) Appl. No.: 10/451,175

(22) PCT Filed: Dec. 21, 2001
(86) PCT No.: PCT/FR01/04144

(30) Foreign Application Priority Data
Dec. 29, 2000 (FR) 00/17266

(51) Int. Cl. H01L 29/04; H01L 31/036; H01L 31/0376; H01L 31/20

(52) U.S. Cl. 257/53

(57) ABSTRACT

Optical semiconductor device, characterized in that it comprises a semiconductor component (2), one front face of which has an optical sensor (3), a transparent plate (6), a rear face of which has electrical connection tracks or lines (8), attachment means (5,10,11) in order to attach the front face of the said semiconductor component to the rear face of the said transparent plate, electrical connection means (5) in order to electrically connect the said semiconductor component to the said electrical connection lines, and encapsulation means comprising a material for encapsulating the said connection means (5) and the periphery of the said semiconductor component (2) on the rear face of the said transparent plate (6), so as to form a peripheral sealing ring (11) between the said semiconductor component and the rear face of the said transparent plate, the said electrical connection lines (8) lying under the said sealing ring and outside the latter.

The present invention relates to an optical semiconductor device fitted with a semiconductor component, one face of which has an optical sensor.

In the prior art, the optical semiconductor components are fitted in the bottom of the cavity of encapsulation packages which have an attached lid made of a transparent material, the bottom wall of the package being used to provide electrical connections outside the component. Such arrangements are bulky and expensive.

The aim of the present invention is, in particular, to improve and simplify the optical semiconductor devices, especially with the aim of reducing their bulk and their production cost.

The optical semiconductor device according to the invention comprises a semiconductor component, one front face of which has an optical sensor, a plate made of a transparent material, a rear face of which has electrical connection tracks or lines lying outside a free region of this face, attachment means for attaching the front face of the said semiconductor component to the rear face of the said transparent plate in a position such that the said sensor lies in front of the said free region, electrical connection means for electrically connecting the said semiconductor component to the said electrical connection lines, and encapsulation means comprising a material for encapsulating the said electrical connection means and the periphery of the said semiconductor component on the rear face of the said transparent plate, so as to form a peripheral sealing ring between the said semiconductor component and the rear face of the said plate, the said electrical connection lines lying under the said sealing ring and outside the latter.

According to the invention, the said attachment means and the said electrical connection means preferably comprise electrical connection balls inserted between the front face of the said semiconductor component and the rear face of the said transparent plate and placed at the periphery of the said optical sensor.

According to the invention, the said encapsulation means preferably comprise an annular spacer inserted between the front face of the said semiconductor component and the rear face of the said transparent plate and placed at the periphery of the said optical sensor, the said sealing ring lying in the peripheral interface region between the said semiconductor component and the said transparent plate and around the said annular spacer.

According to the invention, the said transparent plate is preferably made of glass.

According to the invention, the device may advantageously be mounted on one face of a printed circuit via attachment and electrical connection balls connected to the said electrical connection lines, the said printed circuit comprising a recess or a passage in which the said semiconductor component lies.

The present invention will be better understood on studying an optical semiconductor device described by way of non-limiting example and illustrated by the drawing in which:

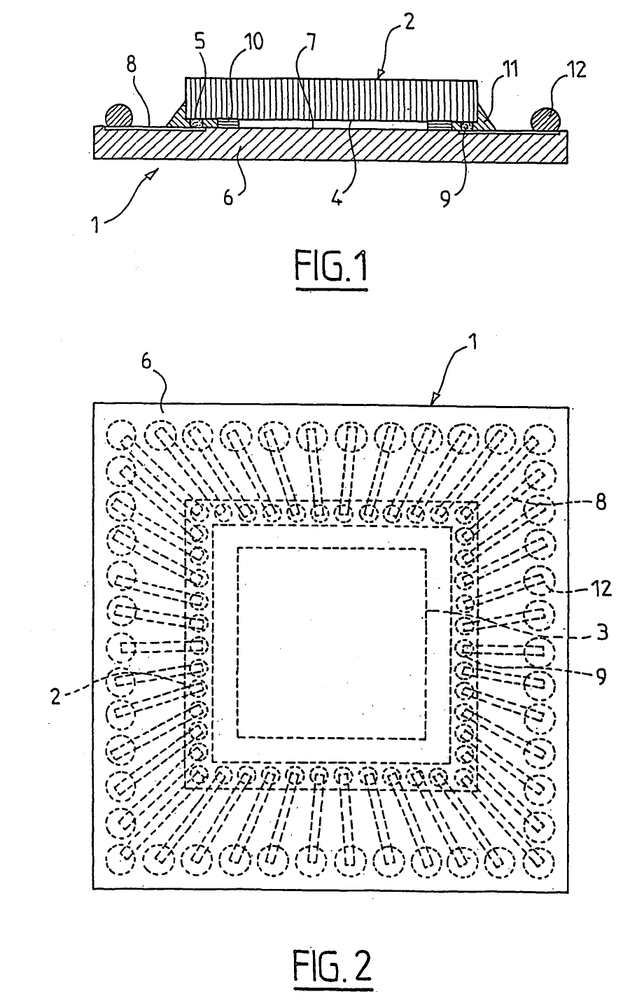

FIG. 1 shows a cross section of an optical semiconductor device according to the present invention;

FIG. 2 shows a front view of the device of FIG. 1;

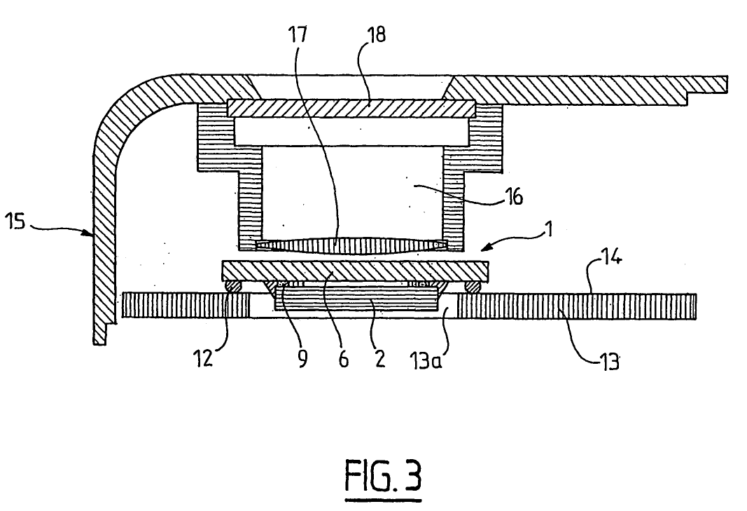

FIG. 3 shows a sectional view of an assembly of the aforementioned device.

The optical semiconductor device 1 shown in the figures comprises an optical semiconductor component 2 which has, on the central part of its front face 4, an optical sensor 3 and, at the periphery and at some distance from this optical sensor 3, electrical connection pads 5.

The optical semiconductor device 1 in addition comprises a plate 6 made of a transparent material such as glass, with a larger area than that of the optical sensor 3, on the rear face 7 of which are made electrical connection tracks or lines 8 which are in the form of segments made of an electrically conducting material. These segments 8 lie in the form of a star on the peripheral part of the rear face 7 leaving a central free region.

The optical component 2 is mounted on and electrically connected to the glass plate 6 via a multiplicity of conducting balls 9, for example made of metal, which are soldered, on the one hand, to the pads 5 of the front face 4 of the optical component 2 and, on the other hand, to the inner ends of the electrical connection segments 8, such that the rear face 4 of the optical component 2 lies at some distance from the rear face 7 of the glass plate 6.

In the space separating the periphery of the optical sensor 3 and the electrical connection balls 5, a seal 10 forming an annular spacer is inserted and is, for example, adhesively bonded between the front surface 4 of the optical component 2 and the rear face 7 of the glass plate 6.

The peripheral interface region between the optical semiconductor component 2 and the rear face 7 of the glass plate 6 is filled with an encapsulation material 11 which forms a sealing ring which, in addition, encapsulates the electrical connection balls 9 and extends inward, being retained therein by the seal 10, the electrical connection segments 8 lying below and outside this sealing ring 11.

Thus, the optical sensor of the optical component 2 lies at some distance from the rear face 7 of the glass plate 6 and the interface region separating them is protected by virtue of the seal 10 and the sealing ring 11.

Electrical connection balls 12, which extend to the periphery and lie at some distance from the optical component 2 and from the sealing ring 11, are soldered to the outer end parts of the electrical connection lines 9.

With reference to FIG. 3, it can be seen that the optical semiconductor component 1 is attached and electrically connected to a printed circuit 13 via electrical connection balls 12. The rear face 7 of the glass plate 6 consequently lies at some distance from a face 14 of the printed circuit 13, the latter having a recess or a through-passage 13a in which the semiconductor component 2 is freely engaged.

The printed circuit 13 is fitted in a container 15 which has a channel 16 lying in front of the front face of the glass plate 6 and in which are arranged, on the side of the glass plate 6, a lens 17 and, on the outside, a glass plate 18.

The optical sensor 3 of the semiconductor component 2 may thus form an optical sensor for light rays passing through the channel 16 of the container 15 by passing through the glass plate 18 and the lens 17 and also passing through the glass plate 6 carrying the optical semiconductor component 1.

The present invention is not limited to the example described above. Many variant embodiments are possible without departing from the scope defined by the appended claims.

1. Optical semiconductor device, characterized in that it comprises:
a semiconductor component (2), one front face of which has an optical sensor (3),
a plate (6) made of a transparent material, a rear face of which has electrical connection tracks or lines (8) lying outside a free region of this face,
attachment means (5, 10, 11) for attaching the front face of the said semiconductor component to the rear face of the said transparent plate in a position such that the said sensor lies in front of the said free region,
electrical connection means (5) for electrically connecting the said semiconductor component to the said electrical connection lines,
and encapsulation means comprising a material for encapsulating the said electrical connection means (5) and the periphery of the said semiconductor component (2) on the rear face of the said transparent plate (6), so as to form a peripheral sealing ring (11) between the said semiconductor component and the rear face of the said transparent plate, the said electrical connection lines (8) lying under the said sealing ring and outside the latter.

2. Device according to claim 1, characterized in that the said attachment means and the said electrical connection means comprise electrical connection balls (5) inserted between the front face of the said semiconductor component and the rear face of the said transparent plate and placed at the periphery of the said optical sensor.

3. Device according to one of claims 1 and 2, characterized in that the said encapsulation means comprise an annular sealing spacer (10) inserted between the front face of the said semiconductor component and the rear face of the said transparent plate and placed at the periphery of the said optical sensor, the said sealing ring (11) lying in the peripheral interface region between the said semiconductor component and the said transparent plate and around the said annular spacer.

4. Device according to one of the preceding claims, characterized in that the said transparent plate (6) is made of glass.

5. Device according to one of the preceding claims, characterized in that it is mounted on one face of a printed circuit (13) via attachment and electrical connection balls (12) connected to the said electrical connection lines, the said printed circuit comprising a recess or a passage in which the said semiconductor component lies.
